(19) United States
(12) Patent Application Publication
(10) Pub. No.: US 2007/0132491 A1
(43) Pub. Date: Jun. 14, 2007

(54) PHASE-LOCKED LOOP WITH COMPENSATED LOOP BANDWIDTH

(76) Inventors: Chang-Fu Kuo, Hsin-Chu City (TW); Tser-Yu Lin, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/164,956

(22) Filed: Dec. 12, 2005

(51) Int. Cl. H03L 7/06

(52) U.S. Cl. 327/157

(57) ABSTRACT

The present invention provides a charge pump in a phase lock loop circuit. The phase lock loop circuit comprises a voltage controlled oscillator (VCO) for producing a variable frequency output signal in response to a VCO control voltage. The charge pump comprises a current generating module for providing a first current, a second circuit for providing a bias current according to a bias control signal, a current mirror circuit that comprises a first current generating unit for generating a third current proportional to a sum of the first current and the second current, and a second current generating unit for generating a fourth current proportional to the sum of the first current and the second current, a first switch for sourcing the third current according to a first control signal and a second switch for sinking the fourth current according to a second control signal.

### BACKGROUND

The present invention relates to a phase-locked loop (PLL) circuit, especially to a PLL circuit having loop bandwidth compensated by utilizing an enhanced charge pump.

In communication systems, a PLL circuit is a device for generating an output signal having a specific phase and a specific frequency, and the loop bandwidth W of the PLL circuit is maintained as stable as possible within an interested range of output frequency of the PLL circuit.

Referring to FIG. 1, which shows the block diagram of a prior art PLL circuit, the PLL circuit 100 contains a phase detector 120, a charge pump 130, a loop filter 140, a voltage controlled oscillator (VCO) 160, and a frequency converter 180. The phase detector 120 receives a reference signal f_{R} and a feedback signal f_{b} and compares the phases of these two signals to generate two signals DOWN and UP, which together represent the phase difference Δ between these two signals. The UP and DOWN signals are transmitted to the charge pump 130 that generates a control current I_{C} accordingly. When the charge pump 130 receives the UP signal, the charge pump 130 sources a current having a magnitude of I_{source} to the loop filter 140. Alternatively, when the charge pump 130 receives the DOWN signal, the charge pump 130 sinks a current having a magnitude of Iₛᵢₙₖ from the loop filter 140. Typically, I_{source} equals to Iₛᵢₙₖ. The loop filter 140 suppresses the high frequency components of the control current I_{C} and then outputs a VCO control voltage Vₜ to control the VCO 160. The output frequency f_{PLL} of the VCO 160 on one hand serves as the output signal of the PLL circuit 100, and on the other hand is down-converted to form the feedback signal f_{b} through the frequency converter 180. Typically, the frequency converter 180 is a frequency divider. The feedback signal f_{b} is then fed back to the phase detector 120.

It is well known that a loop bandwidth W of a PLL circuit is proportional to the square root of the product of the VCO gain K_{VCO} and a charge pump gain K_{CP}. That is, W∝(K_{VCO}×K_{CP})^{1/2}. Generally, the definition of the VCO gain K_{VCO} is the ratio of the frequency variance of the output signal f_{PLL} to the variance of the VCO control voltage Vₜ. The VCO gain K_{VCO} is also referred to as tuning sensitivity. And the charge pump gain K_{CP} is defined to be as the value of I_{source} (or Iₛᵢₙₖ).

Please refer to FIGS. 2, 3, and 4 together. FIG. 2 is a plot of the VCO gain K_{VCO} with respect to the VCO control voltage Vₜ, FIG. 3 is a plot of the charge pump gain K_{CP} with respect to the VCO control voltage Vₜ, and FIG. 4 is a plot of the loop bandwidth W with respect to the VCO control voltage Vₜ. When the PLL circuit is implemented within an integrated circuit, the characteristics of the VCO gain K_{VCO}, as shown in FIG. 2, is usually dependent on the VCO control voltage Vₜ. The VCO gain K_{VCO} cannot be regarded as a constant value within an interested range R of the VCO control voltage Vₜ. Therefore, the loop bandwidth W varies as a function of the VCO control voltage Vₜ as shown in FIG. 4, despite that the charge pump gain K_{CP} is approximately constant as shown in FIG. 3. As a result, the loop bandwidth W varies greatly within an interested range R of the VCO control voltage Vₜ such that the performance of the PLL circuit is varied broadly. In order to improve the performance of the PLL circuit, it is desirable to provide a PLL with compensated loop bandwidth such that the variation of loop bandwidth can be reduced.

### SUMMARY

One objective of the claimed invention is therefore to provide a charge pump with compensated charge pump current in a phase-locked loop circuit to solve the above problem.

According to an embodiment of the claimed invention, a charge pump is disclosed. The charge pump is utilized in a phase-locked loop circuit, which comprises a voltage controlled oscillator (VCO) for producing a variable frequency output signal in response to a VCO control voltage. The charge pump receives a bias control signal, a first control signal, and a second control signal. The charge pump then outputs a control current at an output terminal. The charge pump comprises: a current generating module, a bias circuit, a current mirror circuit, a first switch, and a second switch. The current generating module, which is connected to a node N_{C}, provides a first current. The bias circuit, which is connected to the node N_{C}, provides a second current according to the bias control signal. The current mirror circuit, which is connected to the node N_{C}, comprises a first current generating unit for generating a third current proportional to a sum of the first current and the second current, and a second current generating unit for generating a fourth current proportional to the sum of the first current and the second current. The first switch, which is coupled between the first current generating unit and the output terminal, sources the third current to the output terminal according to the first control signal. The second switch, which is coupled between the second current generating unit and the output terminal, sinks the fourth current from the output terminal according to the second control signal. The bias control signal is generated according to the VCO control voltage.

According to another embodiment of the claimed invention, a phase-locked loop circuit is disclosed. The phase-locked loop circuit is utilized for generating an output signal and comprises a phase detector, a voltage controlled oscillator, a charge pump, and a loop filter. The phase detector receives a reference signal and a feedback signal corresponding to the output signal, and outputs a phase difference signal indicating a phase difference between the feedback signal and the reference signal. The voltage controlled oscillator (VCO) produces the output signal in response to a VCO control voltage. The charge pump receives the phase difference signal and a bias control signal to generate a control current at an output terminal of the charge pump. The loop filter suppresses the high frequency components of the control current to generate the VCO control voltage. The phase difference signal comprises a first phase difference signal and a second phase difference signal. The charge pump comprises a current generating module, a bias circuit, a current mirror circuit, a first switch, and a second switch. The current generating module, which is connected to a node N_{C}, provides a first current. The bias circuit, which is connected to the node N_{C}, provides a second current according to the bias control signal. The current mirror circuit, which is connected to the node N_{C}, comprises a first current generating unit for generating a third current proportional to a sum of the first current and the second current, and a second current generating unit for generating a fourth current proportional to the sum of the first current and the second current. The first switch, which is coupled between the first current generating unit and the output terminal, sources the third current to the output terminal according to the first phase difference signal. The second switch, which is coupled between the second current generating and the output terminal, sinks the fourth current from the output terminal according to the second phase difference signal. The bias control signal is generated according to the VCO control voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a prior art PLL circuit.

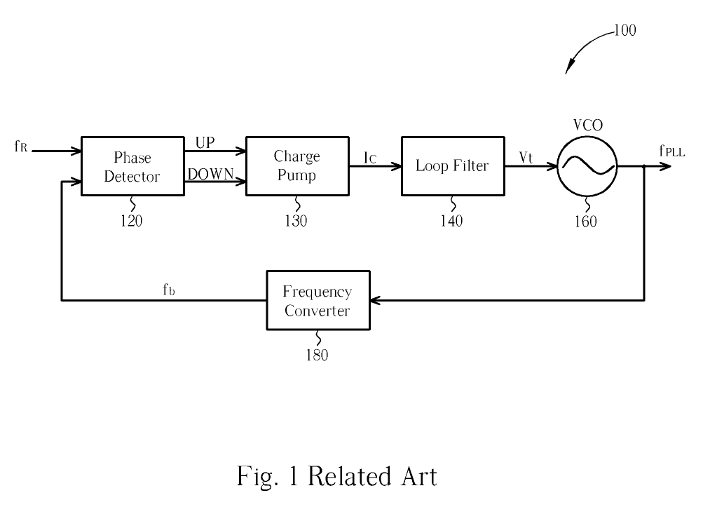

FIG. 2 shows the relationship of the VCO gain K_{VCO} with respect to the VCO control voltage Vₜ according to prior art.

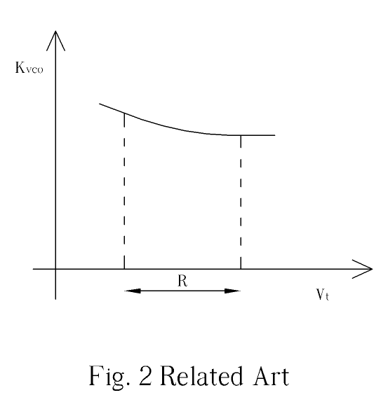

FIG. 3 shows the relationship of the charge pump gain K_{CP} with respect to the VCO control voltage Vₜ according to prior art.

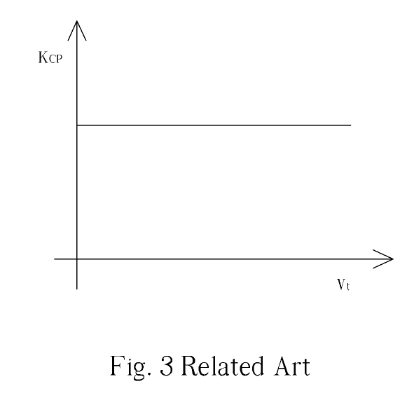

FIG. 4 shows the relationship of the loop bandwidth W with respect to the VCO control voltage Vₜ according to prior art.

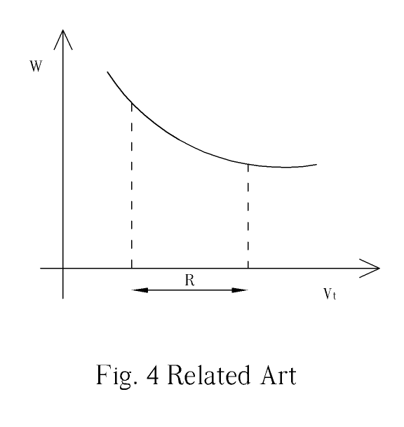

FIG. 5 shows the first type of VCO and the corresponding plot of the VCO gain K_{VCO} with respect to the VCO control voltage Vₜ.

FIG. 6 shows the second type of VCO and the corresponding plot of the VCO gain K_{VCO} with respect to the VCO control voltage Vₜ.

FIG. 7 shows the detailed circuit of a typical charge pump.

FIG. 8 shows the charge pump gain K_{CP} of the typical charge pump 300 with respect to the VCO control voltage Vₜ.

FIG. 9 shows a compensated loop bandwidth W with respect to the VCO control voltage Vₜ according to a first type of VCO.

FIG. 10 shows a compensated loop bandwidth W with respect to the VCO control voltage Vₜ according to a second type of VCO.

FIG. 11 shows a modified charge pump according to a first embodiment of the present invention.

FIG. 12 shows the relation of the current generated by the bias circuit with respect to the control signal Vₜ according to a first embodiment of the bias circuit.

FIG. 13 shows the relation of the current generated by the bias circuit with respect to the control signal Vₜ according to a second embodiment of the bias circuit.

FIG. 14 shows the relation of the current generated by the bias circuit with respect to the control signal Vₜ according to a third embodiment of the bias circuit.

FIG. 15 shows the relation of the current generated by the bias circuit with respect to the control signal Vₜ according to a fourth embodiment of the bias circuit.

FIG. 16 shows a current, which is a combination of the reference current and the current generated by the bias circuit with respect to the control signal Vₜ according to the first and the fourth embodiments of the bias circuit.

FIG. 17 shows a current, which is a combination of the reference current and the current generated by the bias circuit with respect to the control signal Vₜ according to the second and the third embodiments of the bias circuit.

FIG. 18 shows a modified charge pump according to a second embodiment of the present invention.

FIG. 19 shows a current, which is a combination of the reference current and the current generated by the bias circuit with respect to the control signal Vₜ according to the first and the fourth embodiments of the bias circuit.

FIG. 20 shows a current, which is a combination of the reference current and the current generated by the bias circuit with respect to the control signal Vₜ according to the second and the third embodiments of the bias circuit.

FIG. 21 shows a modified charge pump according to a third embodiment of the present invention.

FIG. 22 shows a first embodiment of the reference current generator shown in FIG. 21.

FIG. 23 shows a second embodiment of the reference current generator shown in FIG. 21.

FIG. 24 shows a fifth embodiment of the bias circuit.

FIG. 25 shows a table illustrating the rule of mapping the VCO control voltage Vₜ into the control signals V_{D1} and V_{D2}.

FIG. 26 shows two circuits for converting the VCO control voltage Vₜ into an inverted version Vₜᵢ.

FIG. 27 shows a circuit for generating a fraction of the VCO control voltage.

### DETAILED DESCRIPTION

Since the loop bandwidth W of a PLL circuit is proportional to the square root of the product of the VCO gain K_{VCO} and the charge pump gain K_{CP}, i.e., W∝(K_{VCO}×K_{CP})^{1/2}, and the characteristic of the VCO gain K_{VCO} has been determined once the VCO is fabricated in an integrated circuit, the way to adjust the loop bandwidth W is to tune the charge pump gain K_{CP}.

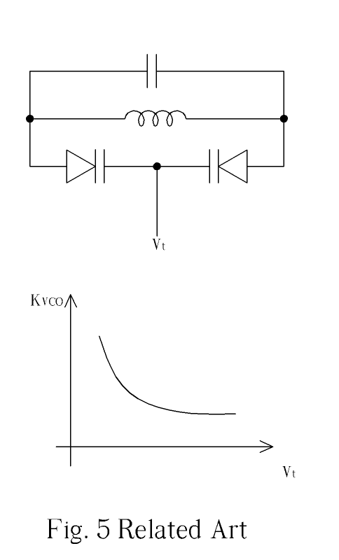

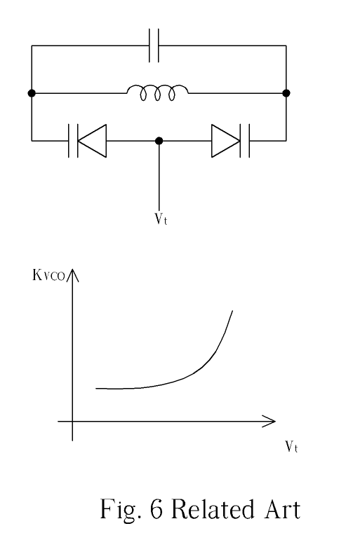

Firstly, it is well known that due to the different architecture of the VCO, the relation of the VCO gain K_{VCO} versus the VCO control voltage Vₜ can be categorized into two types. FIG. 5 shows the typical circuit of the first type of VCO and the corresponding plot of the VCO gain K_{VCO} with respect to the VCO control voltage Vₜ. The VCO gain K_{VCO} decreases as the VCO control voltage Vₜ increases. On the other hand, please refer to FIG. 6. FIG. 6 shows the typical circuit of the second type of VCO and the corresponding plot of the VCO gain K_{VCO} with respect to the VCO control voltage Vₜ. The VCO gain K_{VCO} increases as the VCO control voltage Vₜ increases.

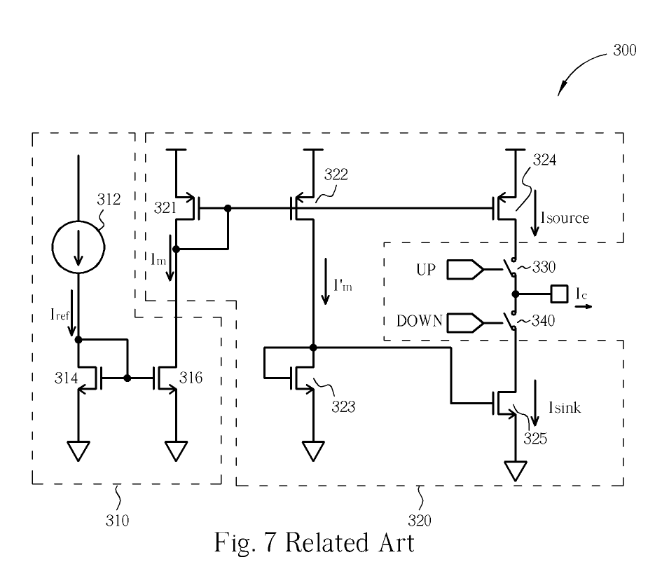

Please refer to FIG. 7. FIG. 7 shows the inner circuit of a typical charge pump. The charge pump 300 contains a current generating module 310 and a current mirror circuit 320, and switches 330 and 340. The current generating module 310 contains a constant current source 312, and two MOSFETs 314 and 316. The constant current source 312 provides a reference current I_{ref}, and the MOSFETs 314 and 316 serve as a current mirror that mirrors the reference current I_{ref} to form a current Iₘ. The current mirror circuit 320 contains five MOSFETs 321, 322, 323, 324, and 325. The MOSFETs 321 and 322 serve as a current mirror that mirrors the current Iₘ to form a current I'ₘ. The MOSFETs 321 and 324 serve as another current mirror that mirrors the current Iₘ to form the current I_{source}. In addition, the MOSFETs 323 and 325 serve as yet another current mirror that further mirrors the current I'ₘ to form the current Iₛᵢₙₖ.

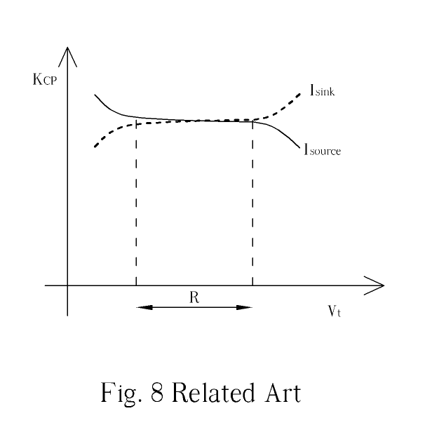

The charge pump 300 also contains two switches 330 and 340, which are respectively controlled by the UP and DOWN signals generated by a phase detector. When the switch 330 is switched on by the UP signal, the current I_{source} passes through the switch 330 to the output terminal of the charge pump 300. That is, the charge pump 300 sources a current having a magnitude of I_{source} to the output terminal of the charge pump 300. On the other hand, when the switch 340 is switched on by the DOWN signal, the charge pump 300 sinks a current having a magnitude of Iₛᵢₙₖ, which is typically equal to I_{source}, from the output terminal of the charge pump 300. The charge pump gain K_{CP} of the charge pump 300, which is defined to be as the value of I_{source} (or Iₛᵢₙₖ), is basically invariant with the VCO control voltage Vₜ during the interested range R of the VCO control voltage Vₜ, as shown in FIG. 8.

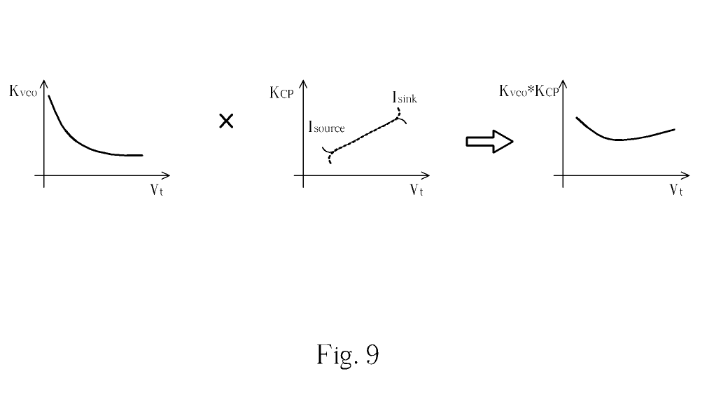

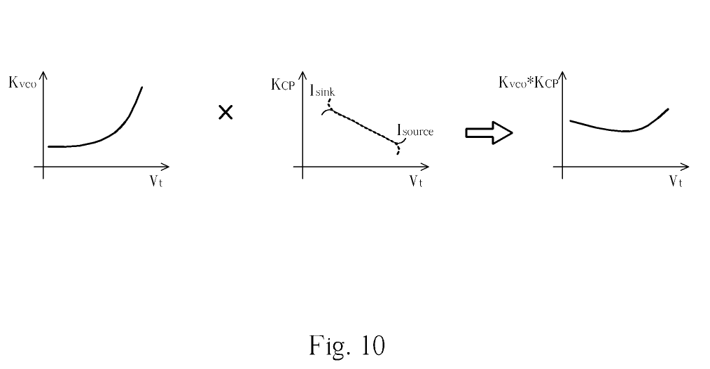

In order to obtain a more stable loop bandwidth W with respect to the VCO control voltage Vₜ, the characteristic of the charge pump gain K_{CP} with respect to the VCO control voltage Vₜ is modified by modifying the circuit design of the charge pump. Taking the first type of VCO shown in FIG. 5 as an example, the VCO gain K_{VCO} is an decreasing function of the VCO control voltage Vₜ, therefore it is desired that the charge pump can modified to have the charge pump gain K_{CP} be an increasing function of the VCO control voltage Vₜ. By this way, the loop bandwidth W is compensated and would become relatively more stable as shown in FIG. 9. On the other hand, for the case of the second type of VCO shown in FIG. 6 wherein the VCO gain K_{VCO} is an increasing function of the VCO control voltage Vₜ, therefore it is desired that the corresponding charge pump can be modified to have the charge pump gain K_{CP} be a decreasing function of the VCO control voltage Vₜ. Hence the loop bandwidth W, as shown in FIG. 10, is compensated and would become relatively more stable.

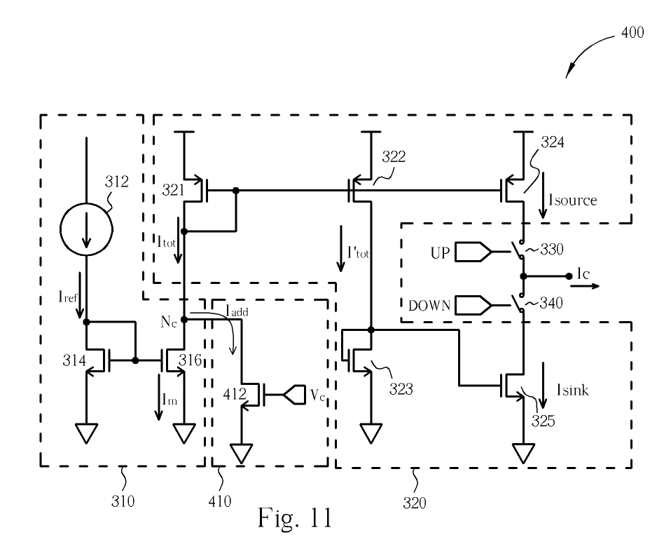

To obtain a modified charge pump gain, an additional bias circuit is added to the typical charge pump 300 according to the present invention. Please refer to FIG. 11. FIG. 11 shows a charge pump 400 according to a first embodiment of the present invention. In addition to the current generating module 310, the current mirror circuit 320, and switches 330 and 340, the charge pump 400 further contains a bias circuit 410.

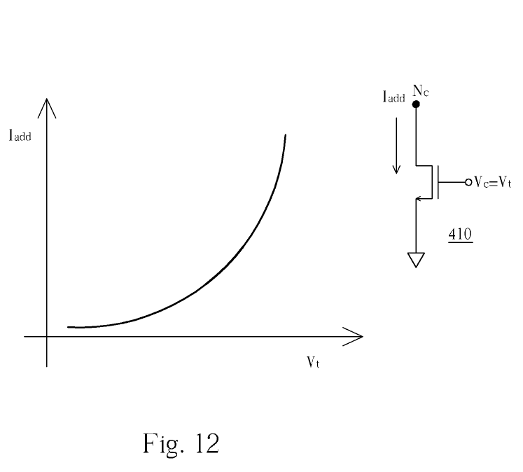

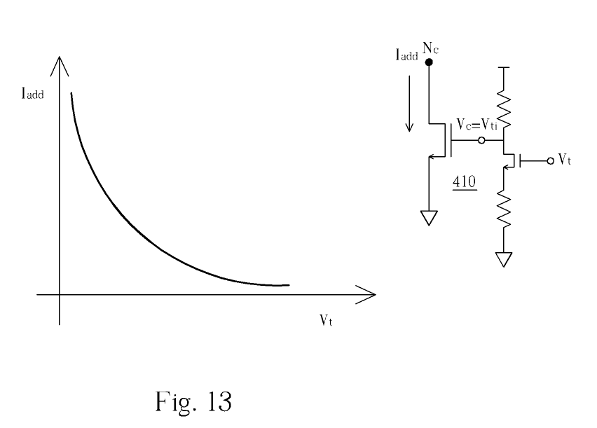

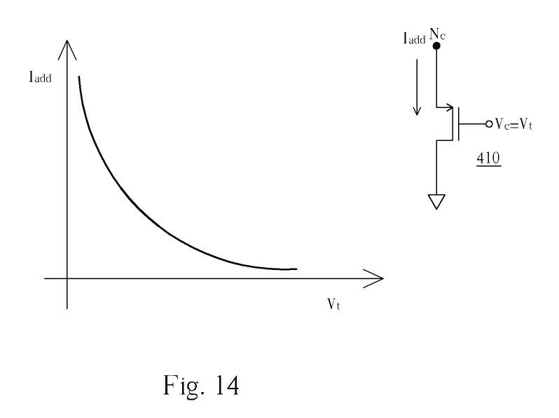

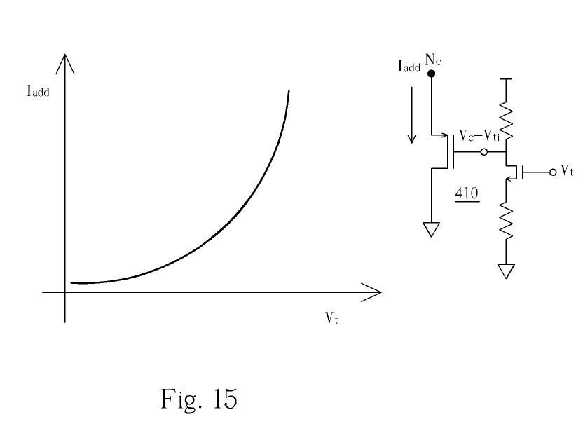

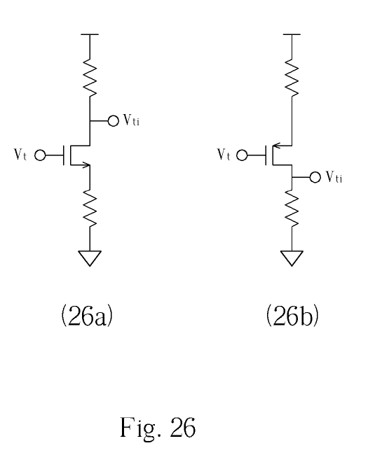

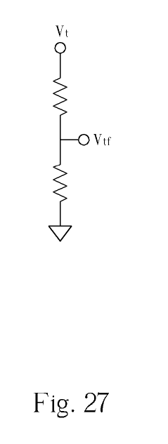

The bias circuit 410 consists mainly of a MOSFET 412 that has a first terminal connected to the node N_{C}, a second terminal connected to ground, and a gate coupled to a control signal V_{C}. The MOSFET 412 could be a P-MOSFET or an N-MOSFET, and the control signal V_{C} is a signal generated according to the VCO control voltage Vₜ. The control signal V_{C} could be just the VCO control voltage Vₜ itself or a signal derived from the VCO control voltage Vₜ, e.g., an inverted version of the VCO control voltage Vₜ, or a fraction of the VCO control voltage Vₜ. As examples well known in the art, an inverted version of the VCO control voltage, denoted by Vₜᵢ, can be obtained via the circuits shown in FIG. 26a or 26b, and a fraction of the VCO control voltage, denoted by V_{tf}, can be obtained via the circuit shown in FIG. 27. Considering that the MOSFET 412 is an N-MOSFET, which is controlled by the VCO control voltage Vₜ, according to the characteristic of the N-MOSFET, the relationship of the current I_{add} generated by the bias circuit 410 with respect to the control signal Vₜ is shown in FIG. 12. On the other hand, for the case of the N-MOSFET controlled by an inverted version of the VCO control voltage, denoted by Vₜᵢ, the characteristic of the current I_{add} is shown in FIG. 13. Similarly, for the case of P-MOSFET, it may be as well controlled by the VCO control voltage (Vₜ) or the inverted version of the VCO control voltage (Vₜᵢ), and the corresponding figures are shown in FIG. 14 and FIG. 15. Please note that, besides a MOSFET, the unit 412 can also be implemented by a BJT for the present invention.

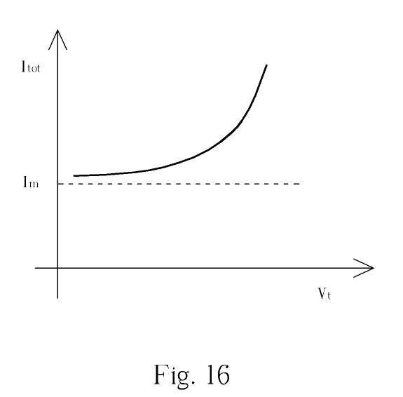

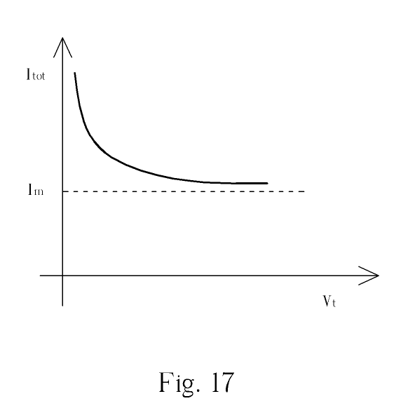

Referring back to FIG. 11, and focusing on the node N_{C}, according to Kirchhoff's current law, we have Iₜₒₜ=Iₘ+I_{add}. Therefore, based on the four embodiments of the bias circuit 410 respectively shown in FIGS. 12 to 15, two types of the characteristics of the current Iₜₒₜ, i.e. increasing Iₜₒₜ and decreasing Iₜₒₜ, can be found as shown in FIGS. 16 and 17 corresponding respectively to FIGS. 12, 15 and FIGS. 13, 14. Afterward, the current Iₜₒₜ is mirrored to finally form the currents I_{source} and Iₛᵢₙₖ by the current mirror circuit 320, and it can be found that the currents I_{source} and Iₛᵢₙₖ will have similar characteristics to the current Iₜₒₜ. As a result, the charge pump gain K_{CP} varies in accordance with the VCO control voltage Vₜ in a manner as show in FIGS. 9 or 10 such that the effect of the varying K_{VCO} on the loop bandwidth W is mitigated. Such a modified charge pump 400 is capable of compensating the loop bandwidth W of the PLL circuit.

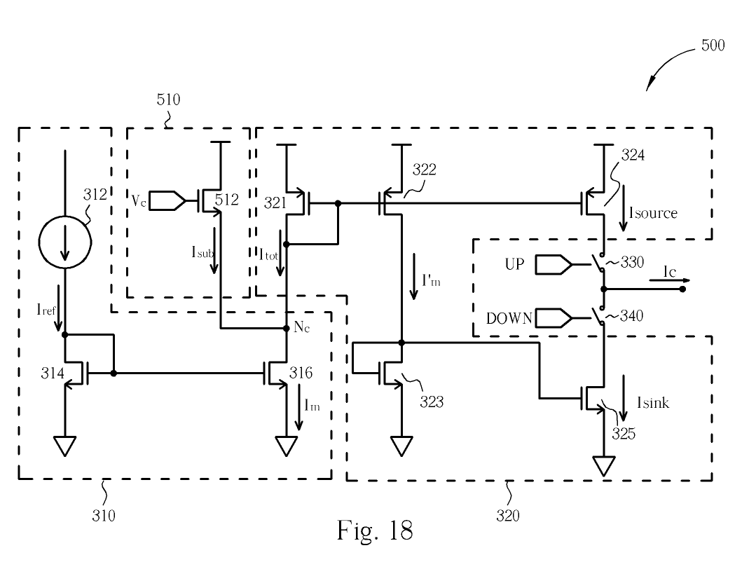

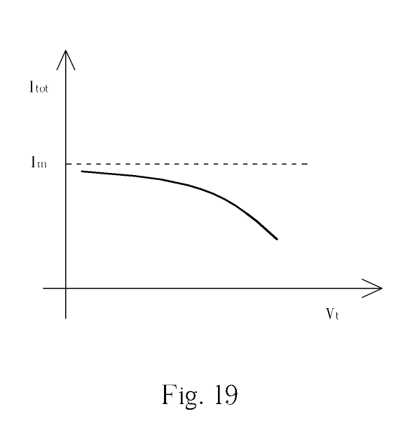

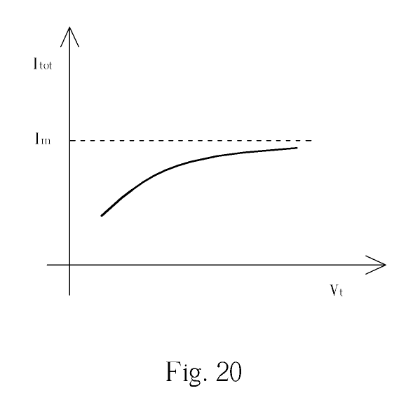

According to a second embodiment of the present invention, a modified charge pump 500 is shown in FIG. 18. Similar to the charge pump 400 shown in FIG. 11, the charge pump 500 consists mainly of the current generating module 310, the current mirror circuit 320, a bias circuit 510, and the switches 330 and 340. Similar to the bias circuit 410, there are four kinds of embodiments of the bias circuit 510 as shown in FIGS. 12-15, but the second terminal of the MOSFET 512 is coupled to a supply voltage rather than ground. According to Kirchhoff's current law, one has Iₜₒₜ=Iₘ−I_{sub}. Based on the four embodiments of the bias circuit 510, it is found that there are two types of characteristics of the current Iₜₒₜ as shown in FIG. 19 and FIG. 20. Next, the current Iₜₒₜ is mirrored to form the currents I_{source} and Iₛᵢₙₖ by the current mirror circuit 320. As a result, charge pump gain K_{CP} varies in accordance with the VCO control voltage Vₜ in a manner as shown in FIGS. 9 or 10 such that the effect of the varying K_{VCO} on the loop bandwidth W is mitigated. Such a modified charge pump 500 is capable of compensating the loop bandwidth W of the PLL circuit. Please note that, besides a MOSFET, the unit 512 can also be implemented by a BJT for the present invention.

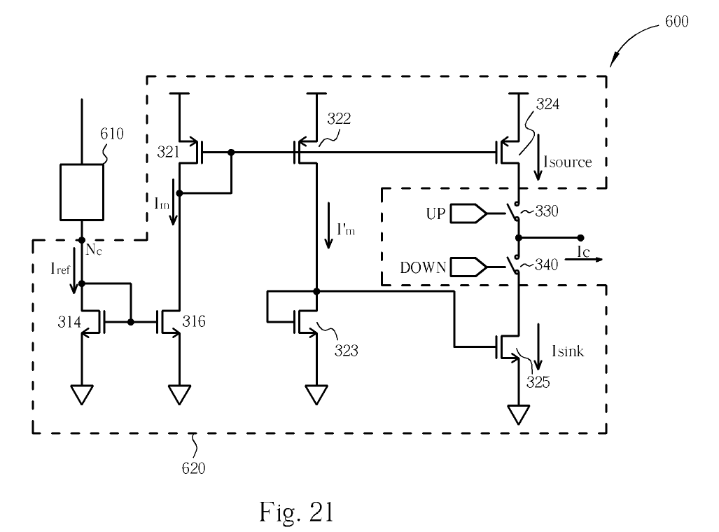

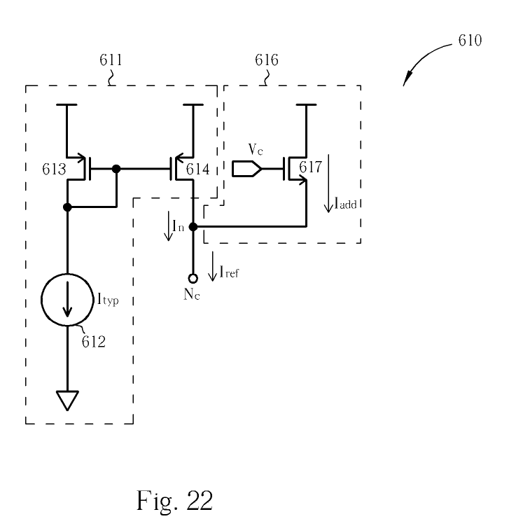

Instead of adding a current to or subtracting a current from the current Iₘ mirrored from the reference current I_{ref}, which is generated by the current generating module 310, in a third embodiment of the present invention, the charge pump gain K_{CP} is modified by directly modifying the reference current I_{ref}. According to a third embodiment of the present invention, a modified charge pump 600 is disclosed and shown in FIG. 21. The charge pump 600 contains a reference current generator 610 and a current mirror circuit 620, and switches 330 and 340. The current mirror circuit 620 is utilized for mirroring the reference current I_{ref} to generate the current I_{source} and the current Iₛᵢₙₖ. A first embodiment of the reference current generator 610 is shown in FIG. 22. The reference current generator 610 comprises a current generating module 611 and a bias circuit 616. The current generating module 611 comprises a constant current source 612 that provides a constant current I_{typ} and a pair of MOSFETs 613 and 614 that form a current mirror for mirroring the constant current I_{typ} to generate a mirrored current Iₙ. The bias circuit 616 is implemented by a MOSFET 617 that has a gate coupled to the control signal V_{C}, a first terminal connected to a supply voltage, and a second terminal connected to the node N_{C}. According to Kirchhoff's current law, the reference current I_{ref} is the sum of the current Iₙ and the current I_{add}. Similarly, the bias circuit 616 has four types of embodiments similar to the four types of embodiments of the bias circuit 510. It can be understood that by introducing the additional current I_{add} to the reference current I_{ref} via the bias circuit 616, the charge pump gain K_{CP} will vary in accordance with the VCO control voltage Vₜ in a manner as show in FIGS. 9 or 10 such that the effect of the varying K_{VCO} on the loop bandwidth W is mitigated. That is, such a modified charge pump 600 is capable of compensating the loop bandwidth W of the PLL circuit. Please note that, besides a MOSFET, the unit 617 can also be implemented by a BJT for the present invention.

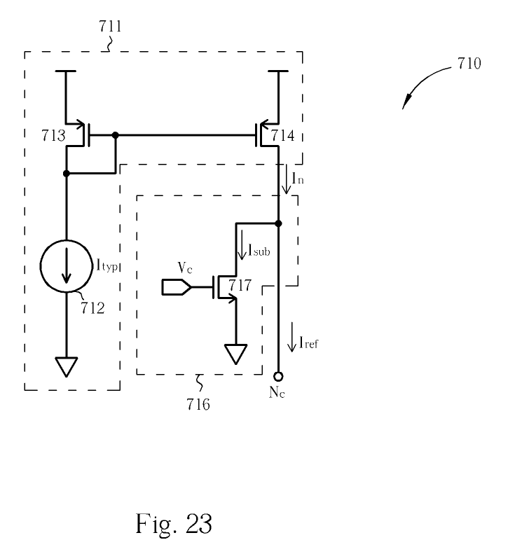

A second embodiment of the reference current generator is shown in FIG. 23. The reference current generator 710 comprises a current generating module 711 and a bias circuit 716. The current generating module 711 comprises a constant current source 712 that provides a constant current I_{typ} and a pair of MOSFETs 713 and 714 that forms a current mirror for mirroring the constant current I_{typ} to generate a mirrored current Iₙ. The bias circuit 716 is implemented by a MOSFET 717 that has a gate coupled to the control signal V_{C}, a first terminal connected to ground, and a second terminal connected to a node N_{C}. According to Kirchhoff's current law, the current Iₙ is the sum of the reference current I_{ref} and the current I_{sub}. That is, I_{ref}=Iₙ−I_{sub}. The bias circuit 716 has four types of embodiments similar to the four types of embodiments of the bias circuit 410. It can be understood that by introducing the additional current I_{sub} to the reference current I_{ref} via the bias circuit 716, the charge pump gain K_{CP} will vary in accordance with the VCO control voltage Vₜ in a manner as show in FIG. 9 or 10 such that the effect of the varying K_{VCO} on the loop bandwidth W is mitigated. That is, such a modified charge pump 600 is capable of compensating the loop bandwidth W of the PLL circuit. Please note that, besides a MOSFET, the unit 717 can also be implemented by a BJT for the present invention.

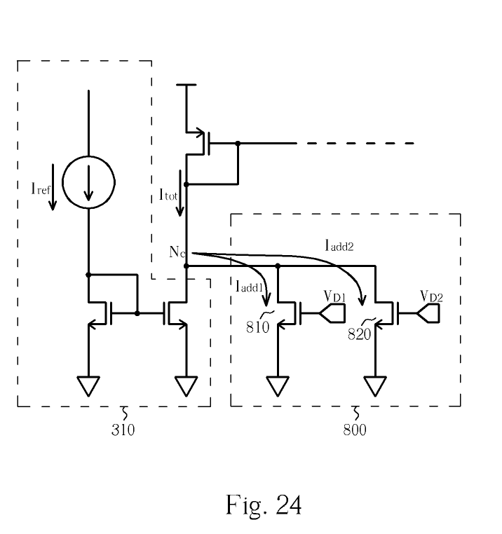

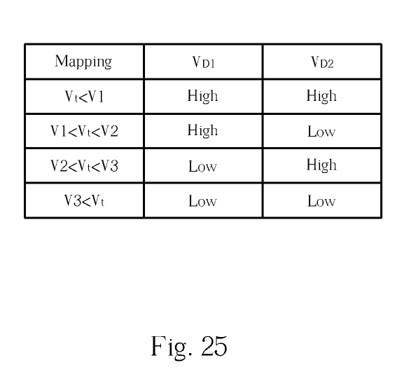

Moreover, either in the charge pumps 400, 500 or in the reference current generator 610, 710, there is a further a fifth embodiment to implement the bias circuit. Referring to FIG. 24, taking the charge pump 400 for example, the original bias circuit 410 is replaced by a bias circuit 800. The bias circuit 800 comprises two MOSFETs 810 and 820, both of which have a first terminal connected to the node N_{C}, a second terminal connected to ground, and are respectively controlled by control signals V_{D1} and V_{D2}. In this embodiment, it is just an example to utilize N-MOSFETs to implement the bias circuit 800; however, P-MOSFETs are also adequate to implement the bias circuit 800. The control signals V_{D1} and V_{D2} are generated by quantizing the VCO control voltage Vₜ. Please refer to FIG. 25. FIG. 25 shows a table illustrating the rule of mapping the VCO control voltage Vₜ into the control signals V_{D1} and V_{D2}. If Vₜ is less than a predetermined voltage level V1, both the control signals V_{D1} and V_{D2} are set high; if Vₜ is higher than the predetermined voltage level V1 but less than a predetermined voltage level V2, the control signal V_{D1} is set high and the control signal V_{D2} is set low; if Vₜ is higher than the predetermined voltage level V2 but less than a predetermined voltage level V3, the control signal V_{D1} is set low and the control signal V_{D2} is set high; if Vₜ is higher than the predetermined voltage level V3, both the control signals V_{D1} and V_{D2} are set low. In short, in this embodiment, the VCO control voltage Vₜ is quantized to form the control signals V_{D1} and V_{D2}, and therefore the current Iₜₒₜ has four different choices to compensate the loop bandwidth of the PLL circuit:

$${I}_{tot} = \{ \begin{matrix}{I}_{ref} + {I}_{add 1} + {I}_{add 2} & {V}_{t} < V 1 \\ {I}_{ref} + {I}_{add 1} & V 1 < {V}_{t} < V 2 \\ {I}_{ref} + {I}_{add 2} & V 2 < {V}_{t} < V 3 \\ {I}_{ref} & V 3 < {V}_{t}\end{matrix}$$

In summary, based on the fact that a loop bandwidth W of a PLL circuit is proportional to the square root of the product of the VCO gain K_{VCO} and a charge pump gain K_{CP}, the loop bandwidth W can then be compensated by modifying the charge pump gain K_{CP}. The detailed circuit of a charge pump is modified in two ways: one is to add a bias circuit directly to the charge pump to adjust the control current I_{C} output by the charge pump, and the other is to add a bias circuit to the core current generating circuit of the charge pump to directly adjust the reference current utilized by the charge pump. In both conditions, there are several methods disclosed to implement the bias circuit. Consequently, a loop bandwidth W of a PLL circuit could be compensated such that the loop bandwidth W of the PLL circuit is maintained as steady as possible within an interested range of output frequency of the PLL circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A charge pump in a phase-locked loop circuit, which comprises a voltage controlled oscillator (VCO) for producing a variable frequency output signal in response to a VCO control voltage, the charge pump receiving a bias control signal, a first control signal, and a second control signal and outputting a control current at an output terminal, comprising:
a current generating module, connected to a node N_{C}, for providing a first current;
a bias circuit, connected to the node N_{C}, for providing a second current according to the bias control signal;
a current mirror circuit, connected to the node N_{C}, comprising a first current generating unit for generating a third current proportional to a sum of the first current and the second current, and a second current generating unit for generating a fourth current proportional to the sum of the first current and the second current;
a first switch coupled between the first current generating unit and the output terminal for sourcing the third current to the output terminal according to the first control signal;
a second switch coupled between the second current generating unit and the output terminal for sinking the fourth current from the output terminal according to the second control signal;
wherein the bias control signal is generated according to the VCO control voltage.

2. The charge pump of claim 1 wherein the bias control signal is equal to the VCO control voltage.

3. The charge pump of claim 1 wherein the bias control signal is equal to an inverted version of the VCO control voltage.

4. The charge pump of claim 1 wherein the bias control signal is equal to a fraction of the VCO control voltage.

5. The charge pump of claim 1 wherein the bias control signal is generated by quantizing the VCO control voltage.

6. The charge pump of claim 1 wherein the bias circuit comprises a transistor having a first terminal, a second terminal, and a control terminal, wherein the control terminal is coupled to the bias control signal, the first terminal is coupled to ground, and the second terminal is coupled to the node N_{C}.

7. The charge pump circuit of claim 1 wherein the bias circuit comprises one transistor having a first terminal, a second terminal, and a control terminal, wherein the control terminal is coupled to the bias control signal, the first terminal is coupled to ground, and the second terminal is coupled to the node N_{C}.

8. The charge pump circuit of claim 1 wherein the bias circuit comprises a transistor having a first terminal, a second terminal, and a control terminal, wherein the control terminal is coupled to the bias control signal, the first terminal is coupled to a supply voltage, and the second terminal is coupled to the node N_{C}.

9. The charge pump circuit of claim 1 wherein the bias circuit comprises one transistor having a first terminal, a second terminal, and a control terminal, wherein the control terminal is coupled to the bias control signal, the first terminal is coupled to a supply voltage, and the second terminal is coupled to the node N_{C}.

10. A phase-locked loop circuit for generating an output signal, comprising:
a phase detector for receiving a reference signal and a feedback signal corresponding to the output signal, and outputting a phase difference signal indicating a phase difference between the feedback signal and the reference signal;
a voltage controlled oscillator (VCO) for producing the output signal in response to a VCO control voltage;
a charge pump, for receiving the phase difference signal and a bias control signal to generate a control current at an output terminal of the charge pump; and
a loop filter for filtering the control current to generate the VCO control voltage,
wherein the phase difference signal comprises a first phase difference signal and a second phase difference signal, and the charge pump comprises:
a current generating module, connected to a node N_{C}, for providing a first current;
a bias circuit, connected to the node N_{C}, for providing a second current according to the bias control signal;
a current mirror circuit, connected to the node N_{C}, comprising a first current generating unit for generating a third current proportional to a sum of the first current and the second current, and a second current generating unit for generating a fourth current proportional to the sum of the first current and the second current;
a first switch coupled between the first current generating unit and the output terminal for sourcing the third current to the output terminal according to the first phase difference signal; and
a second switch coupled between the second current generating and the output terminal for sinking the fourth current from the output terminal according to the second phase difference signal,
wherein the bias control signal is generated according to the VCO control voltage.

11. The phase-locked loop circuit of claim 10 wherein the feedback signal is equal to the output signal.

12. The phase-locked loop circuit of claim 10 further comprising:
a frequency divider coupled between the VCO and the phase detector for receiving the output signal to generate the feedback signal.

13. The phase-locked loop circuit of claim 10 wherein the bias control signal is equal to the VCO control voltage.

14. The phase-locked loop circuit of claim 10 wherein the bias control signal is equal to an inverted version of the VCO control voltage.

15. The phase-locked loop circuit of claim 10 wherein the bias control signal is equal to a fraction of the VCO control voltage.

16. The phase-locked loop circuit of claim 10 wherein the bias control signal is generated by quantizing the VCO control voltage.

17. The phase-locked loop circuit of claim 10 wherein the bias circuit comprises a transistor having a first terminal, a second terminal, and a control terminal, wherein the control terminal is coupled to the bias control signal, the first terminal is coupled to ground, and the second terminal is coupled to the node N_{C}.

18. The phase lock loop circuit of claim 10 wherein the bias circuit comprises one transistor having a first terminal, a second terminal, and a control terminal, wherein the control terminal is coupled to the bias control signal, the first terminal is coupled to ground, and the second terminal is coupled to the node N_{C}.

19. The phase-locked loop circuit of claim 10 wherein the bias circuit comprises a transistor having a first terminal, a second terminal, and a control terminal, wherein the control terminal is coupled to the bias control signal, the first terminal is coupled to a supply voltage, and the second terminal is coupled to the node N_{C}.

20. The phase-locked loop circuit of claim 10 wherein the bias circuit comprises one transistor having a first terminal, a second terminal, and a control terminal, wherein the control terminal is coupled to the bias control signal, the first terminal is coupled to a supply voltage, and the second terminal is coupled to the node N_{C}.

21. A method for adjusting a control current of a charge pump, the charge pump being in a phase lock loop circuit, which comprises a voltage controlled oscillator (VCO) for producing a variable frequency output signal in response to a VCO control voltage, the charge pump receiving a bias control signal, a first control signal, and a second control signal, the method comprising:
providing a first current;
providing a second current according to the bias control signal;
generating a third current proportional to a sum of the first current and the second current;
generating a fourth current proportional to the sum of the first current and the second current;
sourcing the third current to the output terminal according to the first control signal;
and
sinking the fourth current from the output terminal according to the second control signal,
wherein the bias control signal is generated according to the VCO control voltage.

22. The method of claim 21 wherein the bias control signal is equal to the VCO control voltage.

23. The method of claim 21 wherein the bias control signal is equal to an inverted version of the VCO control voltage.

24. The method of claim 21 wherein the bias control signal is equal to a fraction of the VCO control voltage.

25. The method of claim 21 wherein the bias control signal is generated by quantizing the VCO control voltage.

26. A method for generating an output signal comprising:
generating a phase difference signal indicating a phase difference between a feedback signal and a reference signal;
generating a control current according to the phase difference signal and a bias control signal;
filtering the control current to generate a VCO control voltage;
producing the output signal in response to the VCO control voltage,
wherein the phase difference signal comprises a first phase difference signal and a second phase difference signal, and the step of generating the control current comprises:
providing a first current;
providing a second current according to the bias control signal
generating a third current proportional to a sum of the first current and the second current;
generating a fourth current proportional to the sum of the first current and the second current;
sourcing the third current to the output terminal according to the first control signal; and
sinking the fourth current from the output terminal according to the second control signal,
wherein the bias control signal is generated according to the VCO control voltage.

27. The method of claim 26 wherein the feedback signal is equal to the output signal.

28. The method of claim 26 wherein feedback signal is equal to a fraction of the output signal.

29. The method of claim 26 wherein the bias control signal is equal to the VCO control voltage.

30. The method of claim 26 wherein the bias control signal is equal to an inverted version of the VCO control voltage.

31. The method of claim 26 wherein the bias control signal is equal to a fraction of the VCO control voltage.

32. The method of claim 26 wherein the bias control signal is generated by quantizing the VCO control voltage.
